(19) United States
(12) Patent Application Publication
(10) Pub. No.: US 2013/0193419 A1
(43) Pub. Date: Aug. 1, 2013

(54) ORGANIC ELECTROLUMINESCENT ELEMENT AND DISPLAY APPARATUS INCLUDING THE SAME

(71) Applicant: CANON KABUSHIKI KAISHA, Tokyo (JP)

(72) Inventor: Nobutaka Mizuno, Mobara-shi (JP)

(73) Assignee: CANON KABUSHIKI KAISHA, Tokyo (JP)

(21) Appl. No.: 13/752,196

(22) Filed: Jan. 28, 2013

(30) Foreign Application Priority Data
Jan. 31, 2012 (JP) 2012-017448

(51) Int. Cl. H01L 51/52

(52) U.S. Cl. CPC H01L 51/5271
USPC 257/40

(57) ABSTRACT

An organic electroluminescent element that emits red light includes an organic compound layer provided between a first electrode including a reflective metal film and a second electrode including a translucent metal film. The organic compound layer includes a light-emitting layer. The second electrode is provided on a light extraction side. An optical length L₁ from a light-emitting position to a reflective surface of the first electrode satisfies the following expression:

(−1−(2φ₁/π))×(λ/8)<L₁<(1−(2φ₁/π))×(λ/8)

where λ denotes a maximum peak wavelength in an emission spectrum, and φ₁ denotes a phase shift in radians caused by reflection at the first electrode. A reflectance in a direction from the light-emitting layer toward the second electrode is 60% or higher at the maximum peak wavelength in the emission spectrum.

### BACKGROUND OF THE INVENTION

1. Field of the Invention

The present invention relates to an organic electroluminescent (EL) element and a display apparatus including the same.

2. Description of the Related Art

In recent years, organic electroluminescent (EL) elements, which are self-luminous and operate at low voltages of about several volts, have been attracting attention. Organic EL elements are superior in being of a surface emission type, having light weights, and being highly legible and have been therefore practically applied, as light-emitting apparatuses, to flat-panel displays, lighting apparatuses, head-mounted displays, light sources intended for printheads of electrophotographic printers, and so forth.

Particularly, needs for display apparatuses having low power consumption have been increasing, and further improvement in the luminous efficiency of organic EL elements is expected. One of element configurations that dramatically improve luminous efficiency employs a microcavity method. Luminescent molecules are characterized in intensely emitting light toward a space where “constructive interference” of light occurs. That is, emission patterns are controllable by utilizing optical interference. In the microcavity method, device parameters (film thickness and refractive index) are designed such that “constructive interference” occurs in a direction of light extraction with respect to luminescent molecules.

In general, an organic EL element employing the microcavity method includes a translucent metal film functioning as an electrode provided on a light extraction side thereof, and a reflective metal film functioning as another electrode provided on a side thereof opposite the light extraction side. In an element disclosed by Japanese Patent Laid-Open No. 2003-77681, a film of silver (Ag), which is a highly reflective metal, is provided as a reflective metal film. Furthermore, light at a desired wavelength λ is concentrated on the front side by setting an optical length L between the reflective metal film and the light-emitting position of a light-emitting layer as follows:

L=(2m−(φ/π))×(λ/4)

where φ denotes the phase shift (rad) caused by reflection at the reflective metal film, and m denotes the order of interference. The order of interference m is zero or a positive integer. When m is zero, the optical length L is the minimum positive value that satisfies the above expression.

Furthermore, a translucent metal film composed of a Mg—Ag alloy and having a thickness of 10 nm is provided as the electrode on the light extraction side. In this manner, a cavity structure is provided between the two electrodes.

In the microcavity method, configurations around the electrode on the light extraction side are also important. According to Japanese Patent Laid-Open No. 2006-253113, a thin metal film mainly composed of Mg and having a thickness of 17 to 20 nm is provided as a light-extracting electrode. According to Japanese Patent Laid-Open No. 2006-156390, an organic capping layer having a refractive index of 1.7 or higher is provided as an optical adjustment layer above a thin metal film functioning as the electrode on the light extraction side. The organic capping layer is intended for protection of the organic EL element and for improvement in luminous efficiency by suppressing the occurrence of total internal reflection in the electrode on the light extraction side.

The behavior of light in an organic EL element is calculable on the basis of optical simulations, details of which are described by Stefan Nowy et. al., Light Extraction and Optical Loss Mechanisms in Organic Light-Emitting Diodes: Influence of the Emitter Quantum Efficiency, Journal of Applied Physics, volume 104, issue 12, article 123109, Dec. 15, 2008, American Institute of Physics, Melville, N.Y. Methods of calculating the reflectance, the transmittance, the phase shift, and so forth of an optical multilayer thin-film structure are described by M. Kohiyama, “Kogaku Hakumaku no Kiso Riron (Basic Theory of Optical Thin Film—Fresnel Coefficient, characteristic matrix)”, (Japan), Second Edition, The Optronics Co., Ltd., Jul. 23, 2003, pp. 83-113.

In such known elements, the translucent metal film included in the electrode on the light extraction side typically has a thickness of about 10 to 20 nm. Although the optimum thickness of the translucent metal film varies with the order of interference between the reflective metal film and the light-emitting layer and the absorptance of the translucent metal film, the optimum thickness of the translucent metal film is defined substantially uniformly.

### SUMMARY OF THE INVENTION

An embodiment of the present invention provides a display apparatus including an organic EL element having a higher efficiency than that of the known art by setting optimum conditions while taking into consideration the order of interference between a reflective metal film and a light-emitting layer and the absorptance of a translucent metal film.

An embodiment of the present invention has been realized by making diligent analyses of the behavior of light in an organic EL element in relation to the influence of the order of interference and the combination of the translucent metal film and an optical adjustment layer.

According to an aspect of the present invention, an organic electroluminescent element that emits red light includes a first electrode including a reflective metal film, a second electrode including a translucent metal film, an organic compound layer provided between the first electrode and the second electrode and including at least a light-emitting layer, and an optical adjustment layer provided on a light extraction side with respect to the second electrode and having a coherent thickness. An optical length L₁ from a light-emitting position of the light-emitting layer to a reflective surface of the first electrode satisfies the following expression:

(−1−(2φ₁/π))×(λ/8)<L₁<(1−(2φ₁/π))×(λ/8)

where λ denotes a maximum peak wavelength in an emission spectrum, and φ₁ denotes a phase shift in radians caused by reflection at the first electrode. A reflectance and an absorptance in a direction from the light-emitting layer toward the second electrode and the optical adjustment layer are 60 to 75% and below 6%, respectively, at the maximum peak wavelength in the emission spectrum.

According to the above aspect of the present invention, the intensity of a microcavity of the organic EL element and the order of interference between the reflective metal film and the light-emitting layer are optimized, whereby a display apparatus including an organic EL element having an improved luminous efficiency is provided.

Further features of the present invention will become apparent from the following description of exemplary embodiments with reference to the attached drawings.

### BRIEF DESCRIPTION OF THE DRAWINGS

FIGS. 1A and 1B are a schematic perspective view and a schematic sectional view, respectively, of a display apparatus according to a first embodiment of the present invention.

FIG. 2 is a graph illustrating the dependence of luminous efficiency upon reflectance in an organic electroluminescent (EL) element for red-light emission according to the first embodiment of the present invention.

FIG. 3 is a graph illustrating the dependence of reflectance and absorptance upon the thickness of a Ag film in the organic EL element for red-light emission according to the first embodiment of the present invention.

FIG. 4 is a graph illustrating the dependence of luminous efficiency upon reflectance in the organic EL element for red-light emission according to the first embodiment of the present invention.

FIG. 5 is a graph illustrating the dependence of reflectance upon the thickness of a second electrode and the thickness of an optical adjustment layer in the organic EL element for red-light emission according to the first embodiment of the present invention.

FIG. 6 is another graph illustrating the dependence of luminous efficiency upon reflectance in the organic EL element for red-light emission according to the first embodiment of the present invention.

FIG. 7 is a graph illustrating the dependence of reflectance and absorptance upon the thickness of a Mg—Ag film in the organic EL element for red-light emission according to the first embodiment of the present invention.

FIG. 8 is a schematic sectional view of an organic EL element included in a display apparatus according to a second embodiment of the present invention.

FIG. 9 is a graph illustrating the dependence of luminous efficiency and reflectance upon the thickness of an optical adjustment layer in an organic EL element for red-light emission according to the second embodiment of the present invention.

### DESCRIPTION OF THE EMBODIMENTS

Embodiments of the display apparatus according to the present invention will now be described with reference to the attached drawings. Elements not specifically illustrated in the drawings or described in the specification employ technologies that are known in associated technical fields. The following embodiments of the present invention are only exemplary, and the present invention is not limited thereto.

### First Embodiment

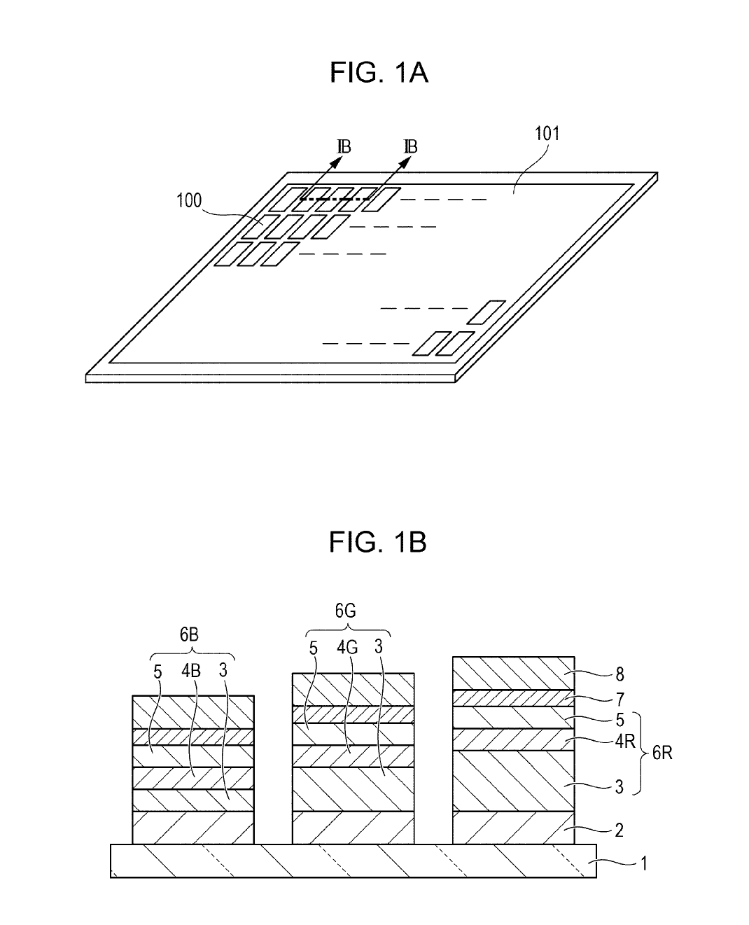

FIG. 1A is a schematic perspective view of a display apparatus according to a first embodiment of the present invention. The display apparatus according to the first embodiment includes a plurality of pixels 100 including organic electroluminescent (EL) elements, respectively. The plurality of pixels 100 are arranged in a matrix pattern and form a display area 101. The term “pixel” refers to an area corresponding to a portion in which light is emitted from one organic EL element. In the display apparatus according to the first embodiment, each of the organic EL elements included in the respective pixels 100 has one luminescent color. Typically, the three primary colors of red (R), green (G), and blue (B) are individually assigned as luminescent colors to the organic EL elements. Any other colors such as white, yellow, and cyan may also be provided. The display apparatus according to the first embodiment includes a plurality of pixel units each including a plurality of pixels 100 having different luminous colors (for example, a pixel 100 that emits red light, a pixel 100 that emits green light, and a pixel 100 that emits blue light). The term “pixel unit” refers to the smallest unit of pixels with which emission of light having a desired color is realized as a mixture of the different colors assigned to those pixels.

FIG. 1B is a schematic sectional view illustrating a part of the display apparatus taken along line IB-IB illustrated in FIG. 1A. The organic EL elements are separated from one another by insulating partitions (not illustrated). Focusing on one organic EL element, a first electrode 2 including a reflective metal film functioning as an anode is provided on a substrate 1. Organic compound layers 6R, 6G, and 6B each include at least a corresponding one of light-emitting layers 4R, 4G, and 4B. The organic compound layer 6R, 6G, or 6B, a second electrode 7 including a translucent metal film functioning as a cathode, and an optical adjustment layer 8 are provided in that order above the first electrode 2. The organic compound layers 6R, 6G, and 6B are each a stack of functional layers including a hole transport layer 3, the light-emitting layer 4, and an electron transport layer 5. The hole transport layer 3 and the electron transport layer 5 may be omitted. Moreover, any of other layers such as a hole injection layer, an electron injection layer, a hole blocking layer, and an electron blocking layer may be added according to need.

The first embodiment concerns a top-emission organic EL element in which light is extracted from a side thereof opposite the substrate 1 (the side is hereinafter referred to as light extraction side). Details of the first embodiment will now be described.

The substrate 1 is a glass substrate provided with driving circuits (not illustrated) such as thin-film transistors (TFTs) including semiconductor members composed of polysilicon (poly-Si), amorphous silicon (a-Si), or the like. Alternatively, the substrate 1 may be a silicon wafer provided with driving circuits.

The first electrode 2 is connected to a corresponding one of the driving circuits, such as TFTs, provided on the substrate 1 and includes a reflective metal film provided for improvement in the luminous efficiency of the organic EL element. The reflective metal film can be composed of a highly reflective metal, specifically, a metal, such as Al or Ag, having a reflectance of 85% or higher with respect to visible light, or an alloy including the same. The first electrode 2 may include only the reflective metal film or may be a stack including the reflective metal film and another layer functioning as a barrier layer and composed of a material having a large work function. Specific examples of the other layer include a transparent electrode composed of indium-tin oxide (ITO), indium-zinc oxide, or the like; a thin-film of metal such as Ti, Mo, or W; and a film of oxide such as MoO₃.

The hole transport layer 3 may include any functions or sub-layers such as a hole injection layer and an electron blocking layer. The electron transport layer 5 may include any functions or sub-layers such as an electron injection layer and a hole blocking layer. In the first embodiment of the present invention, the number of functional layers and the materials composing the layers included in the organic compound layer 6 are not limited. For example, luminescent materials forming the light-emitting layers 4R, 4G, and 4B may be either fluorescent materials or phosphorescent materials, or may be doped into a host material. Moreover, the materials of the light-emitting layers 4R, 4G, and 4B may each include at least one compound, in addition to the luminescent material, for improvement in the performance of the element.

The second electrode 7, which is provided on the light extraction side, includes a translucent metal film, specifically, a film of Ag or Mg. In view of optical absorption, Ag is suitable. In the known art, a translucent metal film mainly composed of Mg is used in many cases in view of electron injection performance. A translucent metal film composed of Ag can also realize superior electron injection performance if combined with alkali metal having superior electron injection performance. Specifically, the following methods are available: a method in which alkali metal is used as an electron injection layer, and a method in which alkali metal is added to the translucent metal film.

The optical adjustment layer 8 is provided above the second electrode 7 and protects the second electrode 7. If the optical adjustment layer 8 has a thickness corresponding to the wavelength of visible light (650 nm) or smaller, the optical adjustment layer 8 has a coherent thickness and affects the reflectance of red-light emission in a direction from the light-emitting layer 4R toward the second electrode 7. That is, it is important to evaluate the organic EL element for red-light emission on the basis of an effective reflectance obtained with the combination of the second electrode 7 and the optical adjustment layer 8. In view of reflectance adjustment, the optical adjustment layer 8 is desired to be composed of a material having a large refractive index but may be composed of either an organic material or an inorganic material.

In a direction from the light-emitting layer 4R for red-light emission toward the first electrode 2, it is important for a microcavity to have a high reflectance and to realize phase matching at a desired wavelength. Phase matching in the direction toward the first electrode 2, which has a high reflectance, is particularly important. The intensity of light to be extracted in the forward direction at a desired wavelength λ is increased if an optical length L₁ from a light-emitting position of the light-emitting layer 4R to the reflective surface of the first electrode 2 satisfies the following expression:

L₁=(2m−(φ₁/π))×(λ/4) (1)

where φ₁ denotes the phase shift (rad) caused by reflection at the first electrode 2, and m denotes the order of interference. The order of interference m is zero or a positive integer. When m is zero, the optical length L₁ is the minimum positive value that satisfies Expression (1). The phase shift φ₁, which varies with the kind of metal, ranges from about −2.79 rad to −1.75 rad. The optical length L₁ is the sum total of values calculated for the respective layers provided between the light-emitting layer 4R and the reflective surface of the first electrode 2, the values each being obtained through the multiplication of a refractive index n by a thickness d. The phase shift (rad) and the reflectance of a stack of thin films are calculable in accordance with a common calculation method for optical multilayer thin-film structures (see “Kogaku Hakumaku no Kiso Riron (Basic Theory of Optical Thin Film—Fresnel Coefficient, characteristic matrix)”, M. Kohiyama, (Japan), Second Edition, The Optronics Co., Ltd., Jul. 23, 2003, pp. 83-113, for example). To produce an advantageous effect of the microcavity at a wide wavelength band and thus improve luminous efficiency in the first embodiment of the present invention, m=0 is desirable. Hence, Expression (1) can be translated into the following expression:

L₁=(−φ₁/π)×(λ/4) (2)

In practical organic EL elements, however, taking into consideration the viewing angle that is in a trade-off relationship with the light extraction efficiency in the forward direction, the above thickness is not necessarily met strictly. Specifically, errors within a range of ±λ/8 with reference to the value of L₁ that satisfies Expression (2) are allowed. Hence, the organic EL element according to the first embodiment of the present invention may satisfy the following expression:

(−1−(2φ₁/π))×(λ/8)<L₁<(1−(2φ₁/π))×(λ/8) (I)

The same applies to phase matching in the direction from the light-emitting layer 4R toward the second electrode 7. The intensity of light to be extracted in the forward direction at a desired wavelength λ is increased if an optical length L₂ from the light-emitting position of the light-emitting layer 4R to the reflective surface of the second electrode 7 satisfies the following expression:

(−1−(2φ₂/π))×(λ/8)<L₂<(1−(2φ₂/π))×(λ/8) (II)

where φ₂ denotes the phase shift (rad) caused by reflection in a case where the structure provided above the second electrode 7 forms one mirror. Hence, the value of the phase shift φ₂ depends on not only the type and the thickness of the translucent metal film but also the refractive index and the thickness of the optical adjustment layer 8.

The errors may fall within a range of ±λ/16. That is, the organic EL element preferably satisfies the following expressions:

(−1−(4φ₁/π))×(λ/16)≦L₁≦(1−(4φ₁/π))×(λ/16) (III)

(−1−(4φ₂/π))×(λ/16)≦L₂≦(1−(4φ₂/π))×(λ/16) (IV)

It is also important in considering the reflectance in the direction from the light-emitting layer 4R toward the second electrode 7 to assume that the structure provided above the second electrode 7 forms one mirror. If the reflectance in the direction toward the second electrode 7 is too low, the cavity effect is insufficient. Therefore, luminous efficiency in the forward direction is not improved. If the reflectance in the direction toward the second electrode 7 is too high, the number of multiple reflections in the organic EL element increases and the internal absorption in the organic EL element increases. Therefore, luminous efficiency in the forward direction is not improved. This means that there is an optimum reflectance in the direction toward the second electrode 7 that provides the maximum luminous efficiency of the organic EL element. The optimum reflectance varies with the configuration of the element.

In the first embodiment of the present invention, it has been found that the optimum reflectance in the direction from the light-emitting layer 4R for red-light emission toward the second electrode 7 varies with the order of interference in the direction from the light-emitting layer 4R toward the first electrode 2. Specifically, when the condition defined by Expression (I) for the smallest order of interference is satisfied, the maximum luminous efficiency is obtained in a range in which the reflectance in the direction toward the second electrode 7 is higher than that of the known art.

The following is an analysis of the relationship between the reflectance in the direction toward the second electrode 7 and the luminous efficiency in a case where the translucent metal film included in the second electrode 7 is composed of Ag. In a simulation described below, the luminous efficiency is optimized within a range in which the optical lengths L₁ and L₂ according to the first embodiment satisfy Expressions (I) and (II), respectively, unless otherwise stated. The simulation is conducted in the same manner as those described by Stefan Nowy et. al., Light Extraction and Optical Loss Mechanisms in Organic Light-Emitting Diodes Influence of the Emitter Quantum Efficiency, Journal of Applied Physics, volume 104, issue 12, article 123109 (2008) and by M. Kohiyama, “Kogaku Hakumaku no Kiso Riron (Basic Theory of Optical Thin Film—Fresnel Coefficient, characteristic matrix)”, (Japan), Second Edition, The Optronics Co., Ltd., Jul. 23, 2003, pp. 83-113, with an internal quantum efficiency of 70%.

### Dependence of Luminous Efficiency of Organic EL Element for Red-Light Emission Upon Reflectance in Direction Toward Second Electrode 7

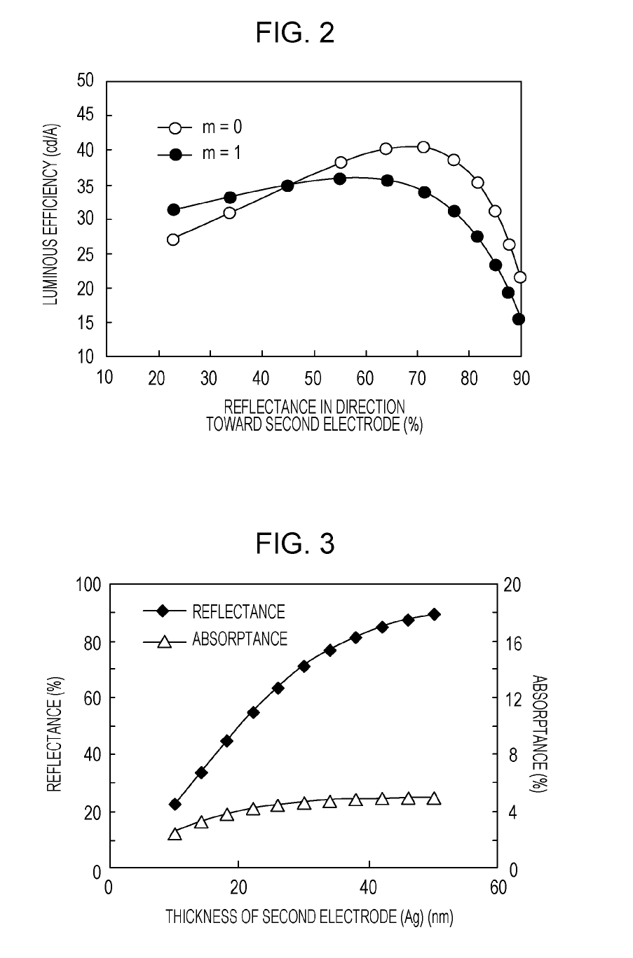

FIG. 2 is a graph illustrating variations in the luminous efficiency with respect to the reflectance in the direction from the light-emitting layer 4R toward the second electrode 7 in a case where the organic EL element for red-light emission (hereinafter referred to as red-light element) according to the first embodiment has a maximum peak wavelength of 570 nm to 650 nm. The reflectance is varied by varying the thickness of the translucent metal film composed of Ag and included in the second electrode 7 from 10 to 50 nm while the optical adjustment layer 8 is composed of a common organic material having a refractive index n of about 1.7 with a thickness of 85 nm. The first electrode 2 is a thick Al film. FIG. 3 is a graph illustrating the relationships between the thickness of the second electrode 7 and the reflectance and the absorptance. The maximum peak wavelength in the spectrum of light emitted from the red-light element according to the first embodiment of the present invention ranges from 570 nm to 650 nm. Wherein the maximum peak wavelength is the wavelength of light emitted by each organic EL element with the greatest optical amplitude in the emission spectrum. If the element is applied to a display apparatus, the maximum peak wavelength is preferably set to 600 nm to 650 nm. If the element is applied to an exposure apparatus, the maximum peak wavelength is preferably set to 570 nm to 620 nm.

As can be seen from FIG. 2, when m=1 in Expression (1), the luminous efficiency reaches the maximum value around a reflectance of 55%. When m=0, the luminous efficiency reaches the maximum value around a reflectance of 70%, which is about 1.2 times that in the case of m=1. When m=1, the cavity effect of extracting light in the forward direction is maintained only at a narrow wavelength band. Therefore, even if the reflectance is increased, the improvement in the luminous efficiency is small. Moreover, the maximum luminous efficiency is obtained at a relatively low reflectance. In contrast, when m=0, the cavity effect of extracting light in the forward direction is maintained at a wide wavelength band. Therefore, the improvement in the luminous efficiency realized at an increase in the reflectance is significant. Moreover, the maximum luminous efficiency is obtained at a relatively high reflectance. Note that the reflectance is taken at a peak wavelength λ of 620 nm in the emission spectrum.

When m=0 in the first embodiment, the luminous efficiency reaches the maximum value when the reflectance in the direction from the light-emitting layer 4R toward the second electrode 7 is around 70%. It is understood that, if the reflectance falls within a range of 60 to 75%, the difference in the luminous efficiency from the maximum luminous efficiency advantageously falls within 5%.

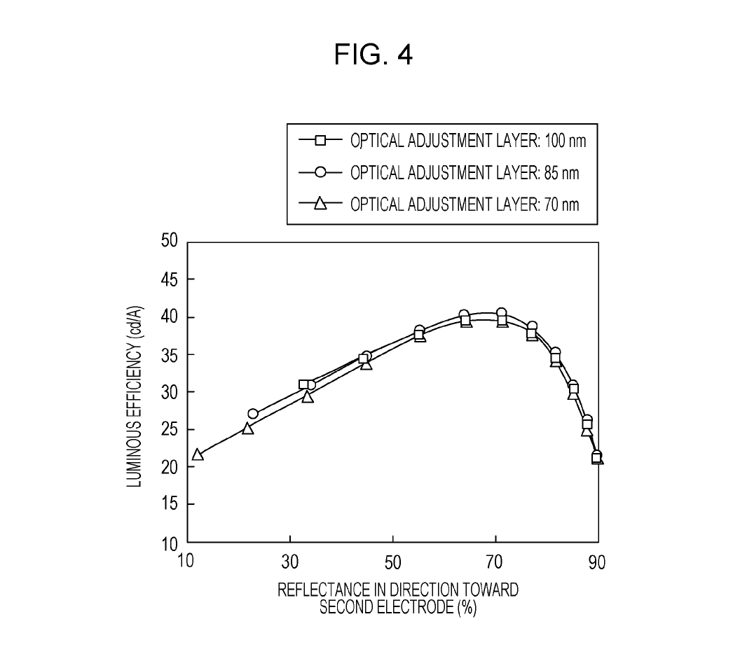

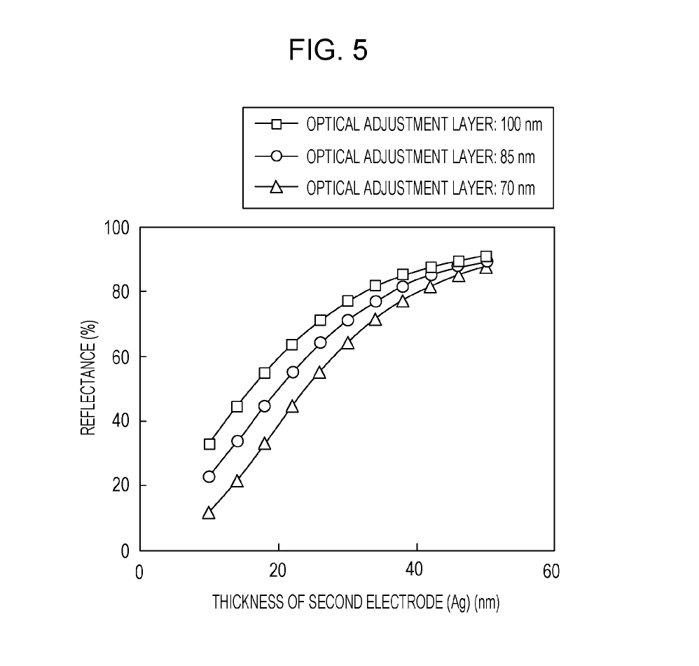

FIG. 4 is a graph illustrating variations in the luminous efficiency with respect to the reflectance in the direction from the light-emitting layer 4R toward the second electrode 7 in different cases where the thickness of the optical adjustment layer 8 according to the first embodiment is set to 70 nm, 85 nm, and 100 nm, respectively. As can be seen from FIG. 4, the variations in the luminous efficiency are defined by the reflectance in the direction from the light-emitting layer 4R toward the second electrode 7, and the luminous efficiency reaches the maximum value around a reflectance of 70% in all cases. This shows that the reflectance in the direction from the light-emitting layer 4R toward the second electrode 7 is fundamentally important. FIG. 5 is a graph illustrating the relationships between the thickness of the second electrode 7 and the reflectance in the respective cases. Values of the thickness of the second electrode 7 in the respective cases at the same reflectance vary with the values of the thickness of the optical adjustment layer 8. Table 1 below summarizes configurations that exhibit the maximum luminous efficiency in the respective cases. This shows that the maximum luminous efficiency is determined by the reflectance calculated from the thickness of the second electrode 7 and the thickness of the optical adjustment layer 8. The reflectance in the direction from the light-emitting layer 4R toward the second electrode 7 is calculated in accordance with the calculation method described by M. Kohiyama, “Basic Theory of Optical Thin Film—Fresnel Coefficient, characteristic matrix (Kogaku Hakumaku no Kiso Riron)”, (Japan), Second Edition, The Optronics Co., Ltd., Jul. 23, 2003, pp. 83-113, assuming that the incident medium is the organic compound layer 6R and the emerging medium is air, and using optical constants summarized in Table 2.

TABLE 1

| | OPTICAL | | |
|---|---|---|---|
| | ADJUSTMENT | | |
| | LAYER | | |
| | 70 nm | 85 nm | 100 nm |
| LUMINOUS EFFICIENCY | 41 | 41 | 41 |
| (cd/A) | | | |
| THICKNESS OF Ag | 34 | 30 | 26 |
| (nm) | | | |
| REFLECTANCE | 72% | 71% | 71% |

TABLE 2

| | n | k |
|---|---|---|
| AIR | 1.00 | 0.00 |
| OPTICAL ADJUSTMENT LAYER 8 | 1.80 | 0.00 |
| SECOND ELECTRODE 7 | 0.13 | 3.88 |
| ORGANIC COMPOUND LAYER 6R | 1.80 | 0.00 |

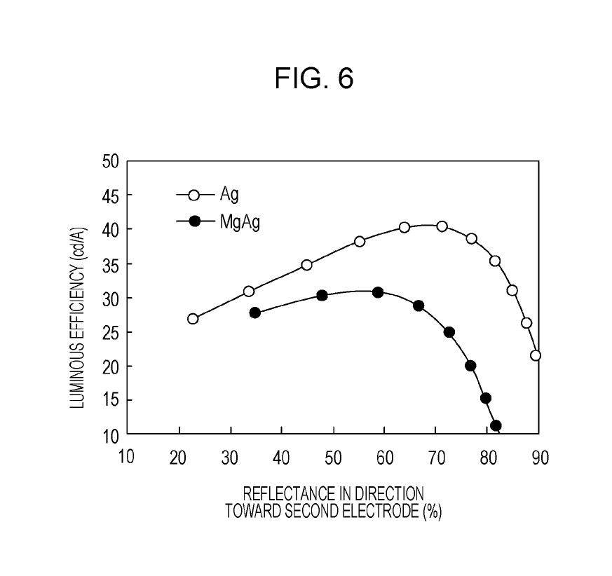

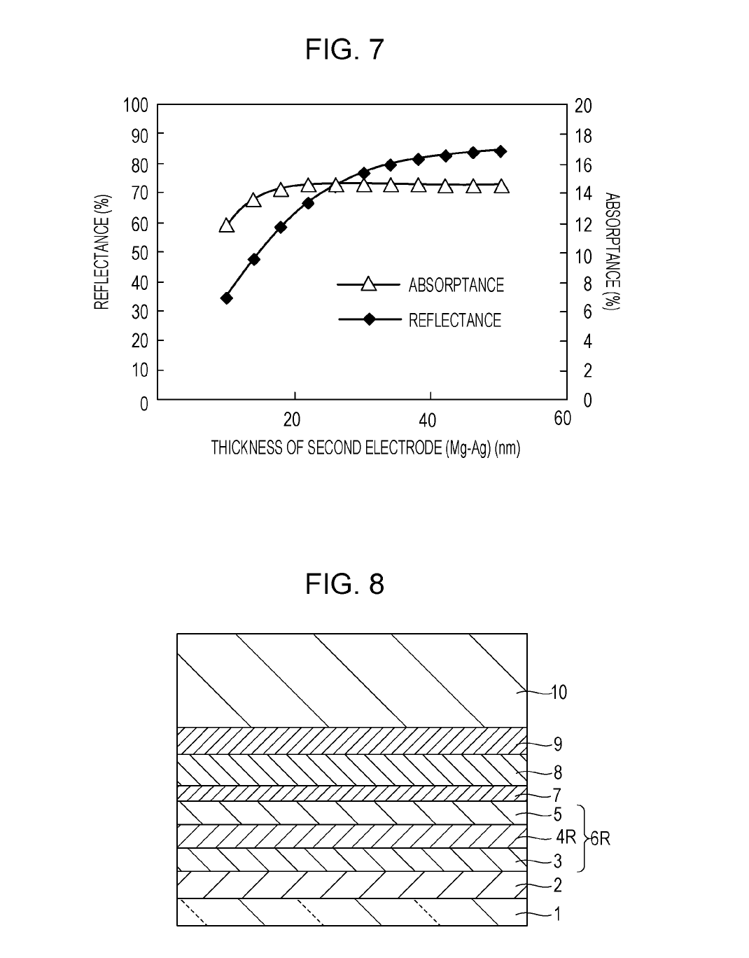

Known technologies tend to be embodied with a thickness of the second electrode 7 of 20 nm or smaller and with a low reflectance in the direction from the light-emitting layer 4R toward the second electrode 7. This is because of the following reasons. In many cases, a configuration corresponding to m=1 in which the organic compound layer 6R can have a large thickness is employed so that the occurrence of short circuit is prevented. Furthermore, a translucent metal film mainly composed of Mg and having an absorptance of 10% or higher is employed. If the absorption by the second electrode 7 is large, the increase in the absorption due to multiple reflections exceeds the cavity effect. Therefore, in a range of reflectance as high as that employed in the first embodiment, the luminous efficiency is lowered. FIG. 6 is a graph illustrating the luminous efficiency obtained when m=0 and the thickness of the optical adjustment layer 8 is 85 nm in a case of a translucent metal film composed of Ag and in a case of a translucent metal film composed of Mg—Ag. As can be seen from FIG. 6, in the case of the translucent metal film composed of Mg—Ag, which has a high absorptance, the luminous efficiency is lowered at a reflectance in the direction from the light-emitting layer 4R toward the second electrode 7 of 70%. Focusing on the maximum luminous efficiency, the case of the translucent metal film composed of Ag exhibits a higher value. FIG. 7 is a graph illustrating the reflectance and the absorptance in the case of the translucent metal film composed of Mg—Ag. The graph shows that the absorptance is over 10%. In contrast, referring to FIG. 3, the absorptance in the case of the translucent metal film composed of Ag is below 6%. Therefore, the luminous efficiency can be increased. The absorptance is obtained by subtracting the sum of the reflectance and the transmittance from 100%.

The reflectance in the direction from the light-emitting layer 4R toward the second electrode 7 is determined by the optical constant of metal to be used as the second electrode 7, the thickness of the second electrode 7, and the refractive index and the thickness of the optical adjustment layer 8. Practically, the optical adjustment layer 8 tends to be composed of a material having a refractive index n of about 1.5 to 2.2. Therefore, to realize a desirable reflectance in the direction from the light-emitting layer 4R toward the second electrode 7 of 60 to 75%, the thickness of the translucent metal film is preferably larger than 20 nm. Moreover, in the first embodiment of the present invention, the lower the absorptance in the direction from the light-emitting layer 4R toward the second electrode 7, the greater the advantageous effect produced. That is, the first embodiment of the present invention is particularly effective in an organic EL element at a long wavelength band in which the absorption at a visible wavelength band is small.

### Second Embodiment

FIG. 8 is a schematic sectional view of an organic EL element for red-light emission included in a display apparatus according to a second embodiment of the present invention. In FIG. 8, elements the same as those illustrated in FIG. 1B are denoted by the same reference numerals as those in FIG. 1B, and description thereof is omitted. In the second embodiment, a protective layer 10 that protects the organic EL element from moisture and oxygen is provided on the light extraction side of the organic EL element. Furthermore, a reflection adjustment layer 9 composed of a material having a lower refractive index than the optical adjustment layer 8 is provided between the optical adjustment layer 8 and the protective layer 10. The protective layer 10 can be composed of a material having a high optical transmittance and a superior moistureproof characteristic, specifically, silicon nitride, silicon oxynitride, or the like. Typically, the protective layer 10 has a thickness of 1 μm or larger so as to maintain its moistureproof characteristic. That is, the protective layer 10 can be regarded as an incoherent layer having a thickness sufficiently larger than the coherent thickness. The second embodiment concerns a top-emission organic EL element in which light is extracted from a side thereof opposite the substrate 1. Details of the second embodiment will now be described.

In a microcavity structure that improves luminous efficiency in the forward direction, the following factors are important, as described above: the reflectance and the phase condition on the side of the structure having the first electrode 2 functioning as a reflective electrode, and the reflectance and the phase condition on the side of the structure having the second electrode 7 provided on the light extraction side. The reflective metal film provided on the side having the first electrode 2 can be composed of highly reflective metal. The optical length L₁ from the light-emitting position of the light-emitting layer 4R to the reflective surface of the first electrode 2 satisfies Expression (I) defined above. The phase condition on the side having the second electrode 7 satisfies Expression (II) defined above. In Expression (II), φ₂ denotes the phase shift (rad) caused by reflection in the case where the structure provided on the light extraction side with respect to the second electrode 7 forms one mirror. Hence, φ₂ is determined by the optical constants and the thicknesses of the second electrode 7, the optical adjustment layer 8 having a coherent thickness, and the reflection adjustment layer 9, and by the refractive index of the protective layer 10. The reflectance on the side having the second electrode 7 corresponds to the reflectance in the case where the structure including layers from the second electrode 7 to the protective layer 10 forms one mirror, and is determined by the optical constants and the thicknesses of the second electrode 7, the optical adjustment layer 8 having a coherent thickness, and the reflection adjustment layer 9 having a coherent thickness, and by the refractive index of the protective layer 10. The reflectance on the side having the second electrode 7 is calculated assuming that the emerging medium is the protective layer 10, which is an incoherent layer, and the incident medium is the light-emitting layer 4R.

### Dependence of Luminous Efficiency of Organic EL Element for Red-Light Emission Upon Reflectance in Direction Toward Second Electrode 7

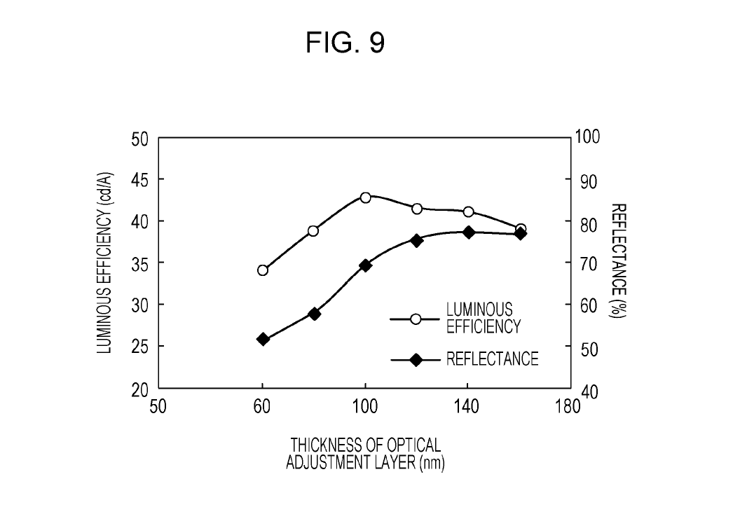

The red-light element according to the second embodiment includes a thick film of Ag alloy functioning as a first electrode 2, a Ag film having a thickness of 26 nm and functioning as a second electrode 7, a LiF film having a thickness of 100 nm and a refractive index of about 1.4 and functioning as a reflection adjustment layer 9, and a silicon nitride (SiN) film having a refractive index of about 2.0 and functioning as a protective layer 10. FIG. 9 is a graph illustrating variations in the reflectance in the direction from the light-emitting layer 4R toward the second electrode 7 and variations in the luminous efficiency in a case where an organic material having a refractive index of about 1.7 is typically employed as the optical adjustment layer 8 and the thickness of the optical adjustment layer 8 is varied. FIG. 9 shows that, when the thickness of the optical adjustment layer 8 is 100 nm, the luminous efficiency reaches the maximum value while the reflectance is about 70%. In the second embodiment, the reflectance is adjusted by using the optical adjustment layer 8. As with the first embodiment, it is understood that a reflectance of 60 to 75% is preferable. The value of the reflectance is taken at a peak wavelength λ of 620 nm in the emission spectrum and is calculated by assuming that the incident medium is the organic compound layer 6R and the emerging medium is the protective layer 10, which is an incoherent layer, and by using optical constants summarized in Table 3.

TABLE 3

| | n | k |
|---|---|---|
| PROTECTIVE LAYER 10 | 1.95 | 0.00 |
| REFLECTION ADJUSTMENT LAYER 9 | 1.39 | 0.00 |
| OPTICAL ADJUSTMENT LAYER 8 | 1.80 | 0.00 |
| SECOND ELECTRODE 7 | 0.13 | 3.88 |
| ORGANIC COMPOUND LAYER 6R | 1.80 | 0.00 |

The display apparatuses according to the embodiments of the present invention are each applicable to mobile apparatuses in which improvement in legibility with high brightness is important, for example, back monitors or electric view finders of image pickup apparatuses such as a digital camera and a digital video camera, displays for mobile phones, and the like. The display apparatuses according to the embodiments of the present invention are each also applicable to apparatuses to be used indoors, because of its low power consumption expected while the brightness is unchanged. The present invention is not limited to any of the above configurations unless departing from the essence thereof, and various applications and modifications thereof are available.

The organic EL elements according to the embodiments of the present invention that emit red light are each applicable to light-emitting elements such as an exposure light source and a lighting element. The exposure light source is applicable to electrophotographic image forming apparatuses. Such an image forming apparatus includes an exposure light source, a photoconductor on which a latent image is to be formed with light from the exposure light source, and a charging member that charges the photoconductor.

### EXAMPLES

### Working Example 1

In Working Example 1, the display apparatus illustrated in FIGS. 1A and 1B was manufactured by the following method.

TFT driving circuits (not illustrated) composed of low-temperature polysilicon were first formed on a glass substrate, and a planarization film (not illustrated) composed of acrylic resin was then provided over the driving circuits, whereby a substrate 1 was obtained.

Subsequently, after an Al—Nd alloy as a first electrode 2 (the anode) was formed by sputtering, MoO₃ was deposited thereon. Furthermore, the resultant body was patterned in correspondence with an intended pattern of light-emitting areas provided for respective pixels 100. Then, the pattern was spin-coated with a polyimide-based resin functioning as an insulating layer. The resultant body was further photolithographically patterned in correspondence with the pattern of light-emitting areas provided for the respective pixels 100.

Subsequently, layers that were to function in combination as an organic compound layer were sequentially formed on the resultant body by vacuum deposition, whereby organic compound layers 6R, 6G, and 6B were obtained. In this step, the hole transport layer 3 was formed with different thicknesses for the different luminescent colors such that a desired chromaticity and a desired luminous efficiency were obtained for each of the organic EL elements configured to emit the luminous colors of R, G, and B. Furthermore, an electron injection layer was formed by codeposition of Bphen and Cs so that sufficient performance of injection from the second electrode 7 was obtained.

Subsequently, a Ag film as a second electrode 7 was formed with a thickness of 26 nm over the organic EL elements for the different luminous colors by vacuum deposition. Furthermore, an organic compound Tris-(8-hydroxyquinoline)aluminium (Alq3) as an optical adjustment layer 8 was formed with a thickness of 85 nm on the Ag film.

Lastly, sealing glass (not illustrated) containing a drying agent and the resultant surface of the glass substrate were sealed together with an ultraviolet-curable resin in a glove box filled with nitrogen.

Table 4 summarizes the results of comparisons of configuration and characteristics between a red-light element according to Working Example 1 satisfying the conditions defined in the embodiments of the present invention and other red-light elements. Relative efficiency is represented by the efficiency ratio with respect to the luminous efficiency (cd/A) in Working Example 1 that is defined as 1. The reflectance and the absorptance were calculated at a maximum peak wavelength λ of 620 nm in the emission spectrum in accordance with the calculation method for optical multilayer thin-film structures.

Configurations of the individual elements summarized in Table 4 will now be described. Working Example 1 and Comparative Example 1 differed from each other in the condition of interference between the first electrode 2 and the light-emitting layer 4R. While Working Example 1 was based on a condition of m=0 in Expression (1), Comparative Example 1 was based on a condition of m=1 in Expression (1). Working Example 1 and Comparative Example 2 differed from each other in the material of the second electrode 7. While Working Example 1 employed Ag, Comparative Example 2 employed a thin metal film obtained by codeposition of Mg and Ag at a mass ratio of 9:1.

As can be seen from the comparison between Working Example 1 and Comparative Example 1, the condition of m=0 concerning the interference between the first electrode 2 and the light-emitting layer 4R exhibited a higher efficiency. Comparing Working Example 1 and Comparative Example 2, Working Example 1 having a lower absorptance exhibited a higher efficiency regardless of the good reflectance in the direction from the light-emitting layer 4R toward the second electrode 7. These results match with the results of the above simulation with no contradictions.

Working Example 1 and Comparative Example 3 differed from each other in the thickness of the second electrode 7, which was composed of Ag. Working Example 1 employed a Ag film having a thickness of 30 nm. In contrast, Comparative Example 3 employed a Ag film that was as thin as 18 nm, resulting in a low reflectance in the direction from the light-emitting layer 4R toward the second electrode 7. Working Example 1 and Comparative Example 4 differed from each other in the thickness of the second electrode 7, which was composed of Ag. Working Example 1 employed a Ag film having a thickness of 30 nm. In contrast, Comparative Example 4 employed a Ag film that was as thick as 38 nm, resulting in a high reflectance in the direction from the light-emitting layer 4R toward the second electrode 7. As can be seen from the comparisons between Working Example 1 and Comparative Examples 3 and 4, when m=0 in Expression (1), Working Example 1, in which the reflectance in the direction from the light-emitting layer 4R toward the second electrode 7 was 60 to 75%, exhibited a higher efficiency. These results match with the results of the above simulation with no contradictions.

The phase shift caused by reflection at the first electrode 2 (the anode) was about −2.62 rad at a maximum peak wavelength λ of 620 nm in the emission spectrum. Hence, the range defined by Expression (I) concerning the optical length L₁ was 52 nm<L<207 nm. Assuming that the light-emitting position was the center of the light-emitting layer 4R, the refractive index of the organic compound layer 6R is about 1.7. Therefore, in Working Example 1, the optical length L₁ from the light-emitting position to the reflective surface of the first electrode 2 is about 106 nm, satisfying Expression (I). Note that the MoO₃ film was as thin as 1 nm or less and is not included in the optical length L₁.

TABLE 4

| | WORKING EXAMPLE 1 | | COMPARATIVE EXAMPLE 1 | | COMPARATIVE EXAMPLE 2 | |
|---|---|---|---|---|---|---|
| | | THICKNESS | | THICKNESS | | THICK- |
| ELEMENT | MATERIAL | (nm) | MATERIAL | (nm) | MATERIAL | NESS (nm) |
| OPTICAL ADJUSTMENT LAYER 8 | Alq3 | 85 | Alq3 | 85 | Alq3 | 85 |
| SECOND ELECTRODE 7 | Ag | 30 | Ag | 30 | MgAg | 26 |
| ELECTRON TRANSPORT LAYER 5 | BCP/Bphen + Cs | 10/40 | BCP/Bphen + Cs | 10/40 | BCP/Bphen + Cs | 10/40 |
| LIGHT-EMITTING LAYER 4R | CBP + Ir(ppy)₃ | 25 | CBP + Ir(ppy)₃ | 25 | CBP + Ir(ppy)₃ | 25 |
| HOLE TRANSPORT LAYER 3 | NPB | 50 | NPB | 213 | NPB | 50 |
| FIRST ELECTRODE 2 | AlNd/Mo0₃ | 150/0.5 | AlNd/Mo0₃ | 150/0.5 | AlNd/Mo0₃ | 150/0.5 |

| | | | | |
|---|---|---|---|---|
| CHARACTERISTIC | CHROMATICITY | (0.686, 0.314) | (0.682, 0.318) | (0.683, 0.317) |
| | RELATIVE | 1.00 | 0.89 | 0.061 |
| | EFFICIENCY | | | |

| | | | |
|---|---|---|---|
| REFLECTANCE | 71.2% | 71.2% | 72.6% |
| ABSORPTANCE | 4.6% | 4.6% | 14.6% |

| | COMPARATIVE EXAMPLE 3 | | COMPARATIVE EXAMPLE 4 | |
|---|---|---|---|---|
| | | THICKNESS | | THICKNESS |
| ELEMENT | MATERIAL | (nm) | MATERIAL | (nm) |
| OPTICAL ADJUSTMENT LAYER 8 | Alq3 | 85 | Alq3 | 85 |
| SECOND ELECTRODE 7 | Ag | 18 | Ag | 38 |
| ELECTRON TRANSPORT LAYER 5 | BCP/Bphen + Cs | 10/40 | BCP/Bphen + Cs | 10/40 |
| LIGHT-EMITTING LAYER 4R | CBP + Ir(ppy)₃ | 25 | CBP + Ir(ppy)₃ | 25 |
| HOLE TRANSPORT LAYER 3 | NPB | 50 | NPB | 50 |
| FIRST ELECTRODE 2 | AlNd/Mo0₃ | 150/0.5 | AlNd/Mo0₃ | 150/0.5 |

| | | | |
|---|---|---|---|
| CHARACTERISTIC | CHROMATICITY | (0.684, 0.316) | (0.681, 0.319) |
| | RELATIVE | 0.86 | 0.88 |
| | EFFICIENCY | | |

| | | |
|---|---|---|
| REFLECTANCE | 44.8% | 81.5% |
| ABSORPTANCE | 3.8% | 4.9% |

### Working Example 2

In Working Example 2, the display apparatus illustrated in FIG. 8 was manufactured. The process from the formation of the hole transport layer 3 to the formation of the second electrode 7 was substantially the same as that employed in Working Example 1, and detailed description thereof is omitted. Working Example 2 differed from Working Example 1 in that the first electrode 2 was a stack of a film of a Ag-Pd-Cu alloy and a film of ITO and in the configuration on the light extraction side with respect to the second electrode 7. In Working Example 2, an Alq3 film as an optical adjustment layer 8 was formed with a thickness of 100 nm and in contact with the second electrode 7, a LiF film as a reflection adjustment layer 9 was subsequently formed thereon with a thickness of 100 nm, and a SiN film as a protective layer 10 was subsequently formed thereon with a thickness of 6 μm by chemical vapor deposition (CVD).

Table 5 summarizes the results of comparison of configuration and characteristics between the red-light element according to Working Example 2 and a comparative red-light element. Comparative Example 5 was the same as Working Example 2 except that the optical adjustment layer 8 had a thickness of 60 nm. Relative efficiency is represented by the efficiency ratio with respect to the luminous efficiency (cd/A) in Working Example 2 that is defined as 1. The reflectance and the absorptance were calculated in accordance with the calculation method for optical multilayer thin-film structures. The results summarized in Table 5 show that Working Example 2, in which the reflectance fell within a range of 60 to 75%, exhibited a higher efficiency than in the case where the thickness of the optical adjustment layer 8 was changed. These results match with the results of the above simulation with no contradictions.

The phase shift caused by reflection at the first electrode 2 (the anode) was about −2.27 rad at a maximum peak wavelength λ of 620 nm in the emission spectrum. Hence, the condition defined by Expression (I) concerning the optical length L₁ was 34 nm<L₁<189 nm. Assuming that the light-emitting position was the center of the light-emitting layer 4R, the refractive index of the organic compound layer 6R is about 1.7 and the refractive index of ITO is about 2.0. Therefore, in Working Example 2, the optical length L₁ from the light-emitting position to the reflective surface of the first electrode 2 is about 92 nm, satisfying Expression (I).

TABLE 5

| | WORKING EXAMPLE 2 | | COMPARATIVE EXAMPLE 5 | |
|---|---|---|---|---|
| | | THICKNESS | | THICKNESS |
| ELEMENT | MATERIAL | (nm) | MATERIAL | (nm) |
| PROTECTIVE LAYER 10 | SiN | 60000 | SiN | 60000 |
| REFLECTION ADJUSTMENT LAYER 9 | LiF | 100 | LiF | 100 |
| OPTICAL ADJUSTMENT LAYER 8 | Alq3 | 100 | Alq3 | 60 |
| SECOND ELECTRODE 7 | Ag | 26 | Ag | 26 |
| ELECTRON TRANSPORT LAYER 5 | BCP/Bphen + Cs | 10/40 | BCP/Bphen + Cs | 10/40 |
| LIGHT-EMITTING LAYER 4R | CBP + Ir(ppy)₃ | 25 | CBP + Ir(ppy)₃ | 25 |
| HOLE TRANSPORT LAYER 3 | NPB | 30 | NPB | 30 |
| FIRST ELECTRODE 2 | AgPdCu/ITO | 150/10 | AgPdCu/ITO | 150/10 |

| | | | |
|---|---|---|---|
| CHARACTERISTIC | CHROMATICITY | (0.680, 0.320) | (0.686, 0.314) |
| | RELATIVE | 1.00 | 0.80 |
| | EFFICIENCY | | |

| | | |
|---|---|---|
| REFLECTANCE | 69.2% | 58.1% |
| ABSORPTANCE | 4.5% | 4.8% |

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-017448 filed Jan. 31, 2012, which is hereby incorporated by reference herein in its entirety.

What is claimed is:

1. An organic electroluminescent element that emits red light, comprising:
a first electrode including a reflective metal film;
a second electrode including a translucent metal film;
an organic compound layer provided between the first electrode and the second electrode and including at least a light-emitting layer; and
an optical adjustment layer provided on a light extraction side with respect to the second electrode and having a coherent thickness,
wherein an optical length L₁ from a light-emitting position of the light-emitting layer to a reflective surface of the first electrode satisfies the following expression:
(−1−(2φ₁/π))×(λ/8)<L₁<(1−(2φ₁/π))×(λ/8)
where λ denotes a maximum peak wavelength in an emission spectrum, and φ₁ denotes a phase shift in radians caused by reflection at the first electrode, and
wherein a reflectance and an absorptance in a direction from the light-emitting layer toward the second electrode and the optical adjustment layer are 60 to 75% and below 6%, respectively, at the maximum peak wavelength in the emission spectrum.

2. The organic electroluminescent element according to claim 1, wherein an optical length L₂ from the light-emitting position of the light-emitting layer to a reflective surface of the second electrode satisfies the following expression:
(−1−(2φ₂/π))×(λ/8)<L₂<(1−(2φ₂/π))×(λ/8)
where λ denotes the maximum peak wavelength in the emission spectrum, and φ₂ denotes a phase shift in radians caused by reflection at the second electrode.

3. The organic electroluminescent element according to claim 1, wherein a reflectance at the reflective surface of the first electrode is at least 85% at the maximum peak wavelength in the emission spectrum.

4. The organic electroluminescent element according to claim 1, wherein the maximum peak wavelength in the emission spectrum is at least 600 nm.

5. The organic electroluminescent element according to claim 1, further comprising a reflection adjustment layer provided on the light extraction side with respect to the optical adjustment layer and having a coherent thickness and a smaller refractive index than the optical adjustment layer.

6. A display apparatus comprising:
the organic electroluminescent element according to claim 1 that emits red light;
an organic electroluminescent element that emits green light; and
an organic electroluminescent element that emits blue light.
